(19) United States
(12) Patent Application Publication
(10) Pub. No.: US 2008/0014759 A1
(43) Pub. Date: Jan. 17, 2008

(54) Method for fabricating a gate dielectric layer utilized in a gate structure

(75) Inventors: Thai Cheng Chua, Cupertino, CA (US); Philip Allan Kraus, San Jose, CA (US); Christopher Sean Olsen, Fremont, CA (US); Cory Czarnik, Saratoga, CA (US); Chikuang Charles Wang, San Jose, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/485,546

(22) Filed: Jul. 12, 2006

(51) Int. Cl. H01L 21/469

(52) U.S. Cl. 438/763; 257/E21.487

(57) ABSTRACT

Methods for forming a gate dielectric layer on a substrate are provided. In one embodiment, the method includes forming a silicon oxide layer on a silicon substrate, depositing a silicon nitride layer on the silicon oxide layer by a thermal process, wherein the silicon oxide layer and the silicon nitride layer are utilized as a gate dielectric layer in a gate structure, and thermally annealing the substrate. In another embodiment, the method includes forming a silicon oxide layer on the silicon substrate with a thickness less than 15 Å, plasma treating the silicon oxide layer, depositing a silicon nitride layer on the silicon oxide layer with a thickness less than 15 Å by a thermal process, wherein the silicon oxide layer and the silicon nitride layer are utilized as a gate dielectric layer in a gate structure, plasma treating the silicon nitride layer; and thermally annealing the substrate.

### BACKGROUND OF THE INVENTION

1. Field of the Invention

Embodiments of the invention generally relate to methods for depositing materials on substrates, and more specifically, to methods for depositing dielectric materials utilized for fabricating a gate structure on substrates.

2. Description of the Related Art

Integrated circuits may include more than one million micro-electronic field effect transistors (e.g., complementary metal-oxide-semiconductor (CMOS) field effect transistors) that are formed on a substrate (e.g., semiconductor wafer) and cooperate to perform various functions within the circuit. A CMOS transistor comprises a gate structure disposed between source and drain regions that are formed in the substrate. The gate structure generally comprises a gate electrode and a gate dielectric layer. The gate electrode is disposed over the gate dielectric layer to control a flow of charge carriers in a channel region formed between the drain and source regions beneath the gate dielectric layer.

The gate dielectric layer has a thickness selected about 30 angstroms to 40 angstroms (Å), or less to achieve the desired speed of the transistor. However, conventional thermal silicon oxide (SiO₂) dielectrics with thicknesses below 30 Å often results in undesirable quality and decreased durability. For example, uniformity control of the thin SiO₂ dielectric layer having a thickness less than 30 Å has presented a difficult challenge. Additionally, an undesirable increase in the gate leakage current, i.e., tunneling current, is often found in conventional thin SiO₂ dielectric layer, resulting in an increase in the amount of power consumed by the gate dielectric layer.

Nitridation of the SiO₂ layer has been employed in a manner to reduce the thickness of the SiO₂ dielectric layer to below 30 Å. Plasma nitridation is used to incorporate nitrogen into the gate oxide layer. Nitridation provides high nitrogen concentration at the electrode/oxide interface, thereby preventing penetration of impurities into the SiO₂ gate oxide layer. The nitrided SiO₂ dielectric layer has a lower equivalent oxide thickness (EOT), which contributes to gate leakage reduction. Typically, a gate dielectric layer with EOT less 12 Å is desired to achieve acceptable device speed. However, conventional nitridation process often results in penetration of large amounts of nitrogen deep into the interface between the thin SiO₂ gate dielectric layer and the silicon substrate, thereby adversely causing high leakage current and charge carrier mobility decrease in the channel regions.

Therefore, there is a need for an improved method of fabricating gate dielectric layers comprising gate structures for field effect transistors.

### SUMMARY OF THE INVENTION

Methods for fabricating a gate dielectric layer on a substrate in a process tool are provided. In one embodiment, a method for fabricating a gate dielectric layer includes forming a silicon oxide layer on a silicon substrate, depositing a silicon nitride layer on the silicon oxide layer by a thermal process, wherein the silicon oxide layer and the silicon nitride layer form a gate dielectric layer, and thermally annealing the substrate.

In another embodiment, a method for fabricating a gate dielectric layer includes forming a silicon oxide layer on a silicon substrate with a thickness less than 15 Å, depositing a silicon nitride layer on the silicon oxide layer with a thickness less than 15 Å by a thermal process, wherein the silicon oxide layer and the silicon nitride layer form a gate dielectric layer, and thermally annealing the substrate.

In yet another embodiment, a method for fabricating a gate dielectric layer includes forming a silicon oxide layer on the silicon substrate with a thickness less than 15 Å, plasma treating the silicon oxide layer, depositing a silicon nitride layer on the silicon oxide layer with a thickness less than 15 Å by a thermal process, wherein the silicon oxide layer and the silicon nitride layer form a gate dielectric layer, plasma treating the silicon nitride layer, and thermally annealing the substrate.

### BRIEF DESCRIPTION OF THE DRAWINGS

The teachings of the present invention can be readily understood by considering the following detailed description in conjunction with the accompanying drawings, in which:

FIG. 1 illustrates a schematic diagram of an exemplary integrated semiconductor substrate processing system (e.g., a cluster tool) of the kind used in one embodiment of the invention;

FIG. 2 illustrates a flow chart of an exemplary process for depositing dielectric layers on the substrate in the cluster tool in FIG. 1; and

FIGS. 3A-G illustrate a substrate during various stages of the process sequence referred to in FIG. 2.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention generally provide methods for fabricating dielectric materials used in a variety of applications, such as a gate dielectric layer used in field effect transistors fabrication. The improved gate dielectric layer fabricated by the present invention may include a silicon nitride layer deposited over a silicon oxide layer having a total thickness less than about 30 Å, such as less than about 25 Å, while maintaining low equivalent oxide thickness (EOT), low leakage current and high charge carrier mobility in channel regions.

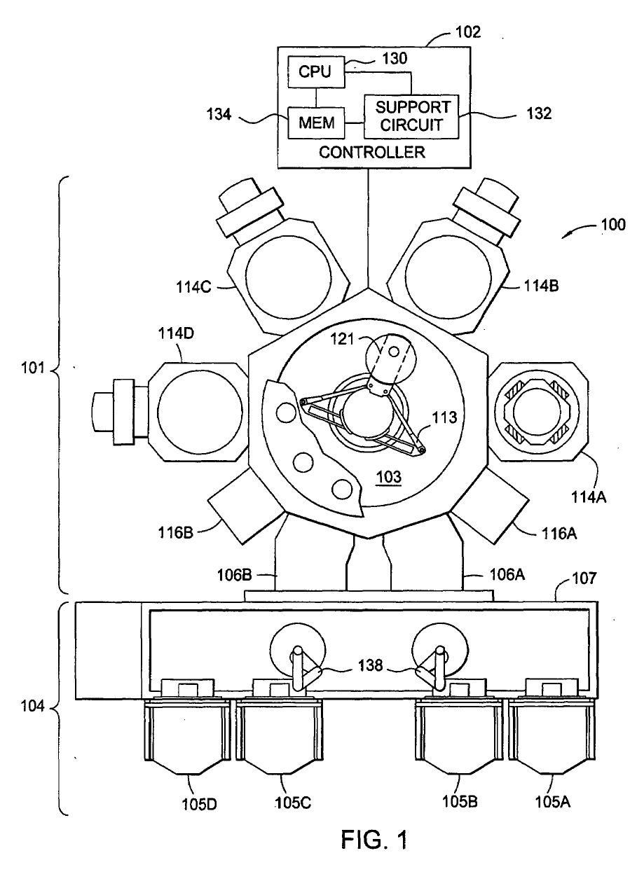

FIG. 1 is a schematic view of an integrated tool 100 which may be utilized for processing semiconductor substrates according to embodiments of the present invention. Examples of the integrated tool 100 include the CENTURA® and ENDURA® integrated tool, all available from Applied Materials, Inc., of Santa Clara, Calif. It is contemplated that the methods described herein may be practiced in other tools having the requisite process chambers coupled thereto.

The tool 100 includes a vacuum-tight processing platform 101, a factory interface 104, and a system controller 102. The platform 101 comprises a plurality of processing chambers 114A-D and load-lock chambers 106A-B, which are coupled to a vacuum substrate transfer chamber 103. The factory interface 104 is coupled to the transfer chamber 103 by the load lock chambers 106A-B.

In one embodiment, the factory interface 104 comprises at least one docking station 107, at least one factory interface robot 138 to facilitate transfer of substrates. The docking station 107 is configured to accept one or more front opening unified pod (FOUP). Four FOUPS 105A-D are shown in the embodiment of FIG. 1. The factory interface robot 138 is configured to transfer the substrate from the factory interface 104 to the processing platform 101 for processing through the loadlock chambers 106A-B.

Each of the loadlock chambers 106A-B have a first port coupled to the factory interface 104 and a second port coupled to the transfer chamber 103. The loadlock chamber 106A-B are coupled to a pressure control system (not shown) which pumps down and vents the chambers 106A-B to facilitate passing the substrate between the vacuum environment of the transfer chamber 103 and the substantially ambient (e.g., atmospheric) environment of the factory interface 104.

The transfer chamber 103 has a vacuum robot 113 disposed therein. The vacuum robot 113 is capable of transferring substrates 121 between the loadlock chamber 106A-B and the processing chambers 114A-D.

In one embodiment, the processing chambers coupled to the transfer chamber 103 may be a chemical vapor deposition (CVD) chamber 114D, a Decoupled Plasma Nitridation (DPN) chamber 114C, a Rapid Thermal Process (RTP) chamber 114B, or an atomic layer deposition (ALD) chamber 114A. Alternatively, different processing chambers, including at least one ALD, CVD, MOCVD, PVD, DPN, RTP chamber, may be interchangeably incorporated into the integrated tool 100 in accordance with process requirements. Suitable ALD, CVD, PVD, DPN, RTP, and MOCVD processing chambers are available from Applied Materials, Inc., among other manufacturers.

In one embodiment, an optional service chamber (shown in 116A-B) may be coupled to the transfer chamber 103. The service chambers 116A-B may be configured to perform other substrate processes, such as degassing, orientation, cool down and the like.

The system controller 102 is coupled to the integrated processing tool 100. The system controller 102 controls the operation of the tool 100 using a direct control of the process chambers 114A-D of the tool 100 or alternatively, by controlling the computers (or controllers) associated with the process chambers 114A-D and tool 100. In operation, the system controller 102 enables data collection and feedback from the respective chambers and system to optimize performance of the tool 100.

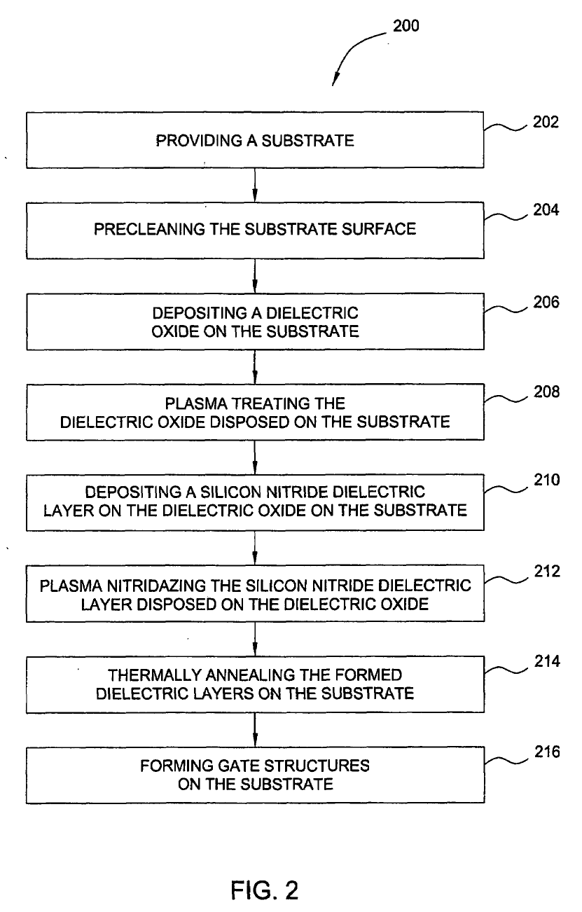

The system controller 102 generally includes a central processing unit (CPU) 130, a memory 134, and support circuit 132. The CPU 130 may be one of any form of a general purpose computer processor that can be used in an industrial setting. The support circuits 132 are conventionally coupled to the CPU 130 and may comprise cache, clock circuits, input/output subsystems, power supplies, and the like. The software routines, such as a method 200 for gate dielectric layer deposition described below with reference to FIG. 2, when executed by the CPU 130, transform the CPU into a specific purpose computer (controller) 102. The software routines may also be stored and/or executed by a second controller (not shown) that is located remotely from the tool 100.

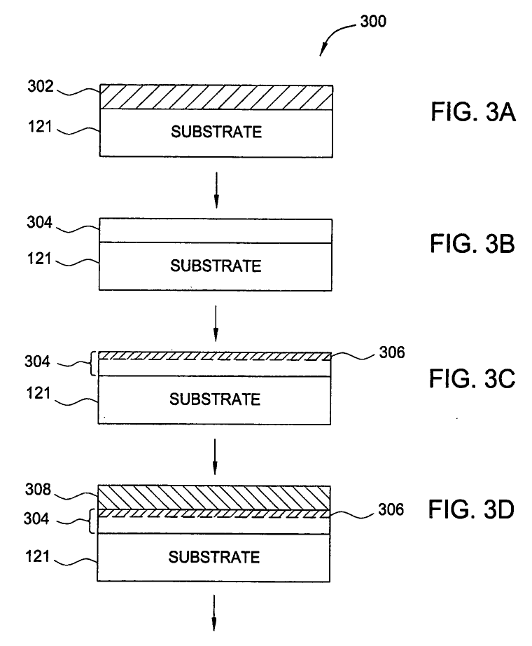

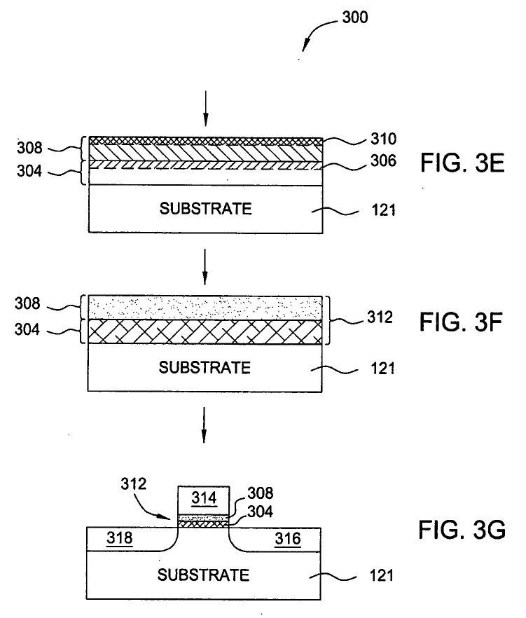

FIG. 2 illustrates a process flow chart of one embodiment of a process 200 for deposition a gate dielectric layer on a substrate in an integrated cluster tool, such as the tool 100 described above. It is also contemplated that the method 200 may be performed in other tools, including those from other manufacturers. FIGS. 3A-3E are schematic, cross-sectional views corresponding to different stages of the process 200.

The method 200 begins at step 202 by providing a substrate 121 utilized to form a gate dielectric layer utilized in a gate structure. The substrate 121, as shown in FIG. 3A, refers to any substrate or material surface upon which film processing is performed. For example, the substrate 121 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 121 may have various dimensions, such as 200 mm or 300 mm diameter wafers, as well as, rectangular or square panels. Unless otherwise noted, embodiments and examples described herein are conducted on substrates with a 200 mm diameter or a 300 mm diameter.

At an optional step 204, precleaning of the substrate 121 may be performed. In one of the processing chambers 114A-D of the tool 100. The precleaning step 204 is configured to cause compounds that are exposed on the surface of the substrate 121 to terminate in a functional group. Functional groups attached and/or formed on the surface of the substrate 121 include hydroxyls (OH), alkoxy (OR, where R=Me, Et, Pr or Bu), haloxyls (OX, where X=F, Cl, Br or I), halides (F, Cl, Br or I), oxygen radicals and aminos (NR or NR₂, where R=H, Me, Et, Pr or Bu). The precleaning process may expose the surface of the substrate 121 to a reagent, such as NH₃, B₂H₆, SiH₄, SiH₆, H₂O, HF, HCl, O₂, O₃, H₂O, H₂O₂, H₂, atomic-H, atomic-N, atomic-O, alcohols, amines, plasmas thereof, derivatives thereof or combination thereof. The functional groups may provide a base for an incoming chemical precursor to attach on the surface of the substrate 121. In one embodiment, the precleaning process may expose the surface of the substrate 121 to a reagent for a period from about 1 second to about 2 minutes. In another embodiment, the exposure period may be from about 5 seconds to about 60 seconds. Precleaning processes may also include exposing the surface of the substrate 121 to an RCA solution (SC1/SC2), an HF-last solution, peroxide solutions, acidic solutions, basic solutions, plasmas thereof, derivatives thereof or combinations thereof. Useful precleaning processes are described in commonly assigned U.S. Pat. No. 6,858,547 and co-pending U.S. patent application Ser. No. 10/302,752, filed Nov. 21, 2002, entitled, “Surface Pre-Treatment for Enhancement of Nucleation of High Dielectric Constant Materials,” and published as US 20030232501, which are both incorporated herein by reference in their entirety.

In an exemplary embodiment of a precleaning process, a native oxide layer 302, as shown in FIG. 3A, may be removed by a HF-last solution. The wet-clean process may be performed in a TEMPEST™ wet-clean system, available from Applied Materials, Inc. In another example, substrate 121 is exposed to water vapor derived from a WVG system for about 15 seconds.

At step 206, a silicon oxide layer 304 is formed on the substrate 121, as shown in FIG. 3B. The silicon oxide formation step 206 may be performed in one of the process chamber 114A-D. The silicon oxide may be deposited a rapid thermal process (RTP), conventional chemical vapor deposition (CVD), rapid thermal-CVD (RT-CVD), plasma enhanced-CVD (PE-CVD), physical vapor deposition (PVD), atomic layer deposition (ALD), atomic layer epitaxy (ALE) or combinations thereof.

In one embodiment, the silicon oxide layer 304 is a thermal oxide layer deposited with an RTP process at a temperature from about 650 degrees Celsius to about 980 degrees Celsius, such as from about 750 degrees Celsius to about 950 degrees Celsius. The silicon oxide layer 304 is deposited having a thin thickness less than about 30 Å, such as less than about 20 Å, for example, about 15 Å or less. A process gas mixture including oxygen gas (O₂) is supplied into the chamber between about 0.5 slm to about 10 slm, such as about 2 slm. The process pressure may be regulated between about 0.5 Torr and about 50 Torr, such as 2 Torr. The deposition process may be performed between about 5 seconds to about 30 seconds. Examples of process chamber used to deposit silicon oxide layer 304 include Radiance® system available from Applied Materials, Inc., such as RTP chamber 114A-D, as shown in FIG. 1.

At an optional step 208, a plasma treatment step may be performed on the silicon oxide layer 304. The plasma treatment step is performed to treat the silicon oxide layer while forming plasma-treated layer 306, as depicted in FIG. 3C. The plasma process may include a decoupled inert gas plasma process performed by flowing an inert gas into a decoupled plasma nitridation (DPN) chamber (i.e., a DPN chamber 114A-D) or a remote inert gas plasma process by flowing an inert gas into a process chamber equipped by a remote plasma system.

In one embodiment, the plasma treatment step 208 is performed in one of the chambers 114A-D that is configured as a DPN chamber. The silicon oxide layer 304 is bombarded with ionic nitrogen formed by flowing nitrogen (N₂) into the DPN chamber. Gases that may be used in the plasma process include nitrogen containing gas, such as N₂ or NH₃, argon (Ar), helium (He), neon, xenon or combinations thereof. The nitrogen gas flowed into the DPN chamber nitridizes the silicon oxide layer 304, forming the treated layer 306 on the upper surface of the silicon oxide layer 304. In one embodiment, the nitrogen concentration treated on the silicon oxide layer 304 may be between about 2E¹⁵ atomic weight percent per square centimeters (at/cm²) and about 8E¹⁵ atomic weight percent per square centimeters (at/cm²).

In one embodiment, the plasma process proceeds for a time period from about 10 seconds to about 300 seconds, for example, from about 30 seconds to about 240 seconds, and in one embodiment, from about 60 seconds to about 180 seconds. Also, the plasma process is conducted at a plasma power setting from about 500 watts to about 3,000 watts, for example, from about 700 watts to about 2,500 watts, for example, from about 900 watts to about 1,800 watts. Generally, the plasma process is conducted with a duty cycle of about 10 percent to about 90 percent, and at a pulse frequency at about 10 kHz. The DPN chamber may have a pressure from about 10 mTorr to about 80 mTorr. The inert gas may have a flow rate from about 10 standard cubic centimeters per minute (sccm) to about 5 standard liters per minute (slm), or from about 50 sccm to about 750 sccm, or from about 100 sccm to about 500 sccm.

At step 210, a silicon nitride layer 308 is deposited on the silicon oxide layer 304, as shown in FIG. 4. In one embodiment, the silicon nitride layer 308 is deposited to a thin thickness of less than about 20 Å, such as less than about 15 Å, for example, about 10 Å or less. The silicon nitride layer 308 along with the silicon oxide layer 304 provides a low equivalent oxide thickness (EOT) unit opposed to the conventional thermal oxide layer, thereby reducing gate leakage and increasing the stability and density of the dielectric materials.

In embodiments depicted in FIG. 3D-3F, the silicon nitride layer 308 is deposited by a thermal chemical vapor deposition (Thermal-CVD) process, such as a low pressure chemical vapor deposition (LPCVD). Examples of process chamber used to deposit silicon nitride layer 308 include SiNgen® Plus system available from Applied Materials, Inc. Alternatively, the silicon nitride layer may be deposited by plasma enhanced-CVD (PE-CVD), physical vapor deposition (PVD), or atomic layer deposition (ALD). The silicon nitride deposition process may be one of the process chamber 114A-D.

In one embodiment, the silicon nitride layer 308 is deposited with a Thermal-CVD process at a temperature from about 400 degrees Celsius to about 800 degrees Celsius, such as from about 500 degrees Celsius to about 700 degrees Celsius, for example, about 600 degrees Celsius. A process gas mixture including a nitrogen containing gas and a silicon containing gas, such as SiH₄, is supplied into the chamber. Suitable nitrogen containing gases include, but not limited to, NH₃, N₂, N₂O, and the like. Suitable silicon containing gases include, but not limited to, SiH₄, Si₂H₆, dichlorosilane (DCS), tetrachlorosilane (TCS), or hexachlorodisilane (HCD) and the like. In one embodiment, the gas mixture may be supplied by a predetermined ratio of the nitrogen containing gas and silicon containing gas ranging between about 1:1 to about 1000:1 into the process chamber. In another embodiment, the gas mixture may be supplying by controlling the gas flow of nitrogen containing gas between about 10 sccm and about 1000 sccm, for example, between about 10 sccm and about 100 sccm, such as about 25 sccm, and silicon containing gas between about 1 sccm and about 100 sccm, for example, between about 1 sccm and about 50 sccm, such as 10 sccm. The process pressure may be regulated between about 0.5 Torr and about 50 Torr, for example, between about 1 Torr and about 25 Torr, such as 5 Torr. The deposition process may be performed between about 30 seconds to about 1800 second.

At an optional step 212, another plasma treatment step, which may be substantially similar to the plasma treatment step 208, may be performed on the silicon nitride layer 308. The plasma step 212 is performed to densify the silicon nitride layer 308 while forming plasma-treated layer 310, as depicted in FIG. 3E. The plasma treatment step 212 may include a decoupled inert gas plasma process performed by flowing an inert gas into a decoupled plasma nitridation (DPN) chamber (i.e., a DPN chamber 114A-D) or a remote inert gas plasma process by flowing an inert gas into a process chamber equipped by a remote plasma system, as described in step 208.

At step 214, the deposited silicon oxide layer 304 and the silicon nitride layer 308 disposed on the substrate 121 is exposed to a thermal annealing process. An example of a suitable RTP chamber in which step 214 may be performed is the CENTURA™ RADIANCE™ RTP chamber, available from Applied Materials, Inc., among others. The thermal annealing process step 214 may be performed in one of the process chambers 114A-D described in FIG. 1.

In one embodiment, the substrate 121 may be thermally heated to a temperature from about 600 degrees Celsius to about 1,200 degrees Celsius. In another embodiment, the temperature may be from about 700 degrees Celsius to about 1,150 degrees Celsius, such as between about 800 degrees Celsius about 1,000 degrees Celsius. The thermal annealing process may have different durations. In one embodiment, the duration of the thermal annealing process may be from about 1 second to about 180 seconds, for example, about 2 seconds to about 60 seconds, such as about 5 seconds to about 30 seconds. At least one annealing gas is supplied into the chamber for thermal annealing process. Examples of annealing gases include oxygen (O₂), ozone (O₃), atomic oxygen (O), water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), derivatives thereof or combinations thereof. The annealing gas may contain nitrogen and at least one oxygen-containing gas, such as oxygen. The chamber may have a pressure from about 0.1 Torr to about 100 Torr, for example, about 0.1 to about 50 Torr, such as 0.5 Torr. In one example of a thermal annealing process, substrate 121 is heated to a temperature of about 1,000 degrees Celsius for about 15 seconds within an oxygen atmosphere. In another example, substrate 121 is heated to a temperature of about 1,100 degrees Celsius for about 10 seconds to about 25 seconds within an atmosphere containing equivalent volumetric amounts of nitrogen and oxygen during the annealing process.

The thermal annealing process of step 214 converts the silicon oxide layer 304 and the silicon nitride layer 308 to a post anneal layer 312, as depicted in FIG. 3F. The thermal annealing process of step 214 repairs any damage caused by plasma bombardment in steps 208, 210, 212 and reduces the fixed charge of post anneal layer 312. The post anneal layer 312 may have a nitrogen concentration with different ranges. In one embodiment, the nitrogen concentration of the post anneal layer 312 is between about 2E¹⁵ atoms/cm² and about 7E¹⁵ atoms/cm². The post anneal layer 312 has a smooth surface having a surface. For example, the layer 312 may have a surface roughness of less than 0.25 nm as inspected by a conventional Atomic Force Microscope. In one embodiment, the post anneal layer 312 may have a combined film thickness of the gate dielectric layer and the silicon oxide layer between about 10 Å to about 30 Å. In another embodiment, the combine thickness may be from about 12 Å to about 28 Å. In yet another embodiment, the thickness may be from about 15 Å to about 25 Å, such as 20 Å.

At step 216, a gate structure may be formed on the substrate 121, as shown in FIG. 3G. After the post anneal layer 312 is formed on the substrate as a gate dielectric layer, a gate electrode 314 may be disposed on post anneal layer 312 utilized to form a gate structure on the substrate 121. Source 318 and drain regions 316 may be created in the substrate 121 by conventional ion implantation process. Details of the process steps, including lithography and etch processes, carried out to form the gate structure on the substrate have been omitted for the sake of brevity.

Thus, methods for fabricating a gate dielectric material that may be used for gate fabrication for field effect transistors have been provided. The method produces an integrated silicon nitride layer and a silicon oxide layer having a total thickness less than 30 Å, such as less than 25 Å, while having a desired low while maintaining low equivalent oxide thickness (EOT), low leakage current and high charge carrier mobility in channel regions.

While the foregoing is directed to embodiments of the invention, other and further embodiments of the invention may be devised without departing from the basic scope thereof, and the scope thereof is determined by the claims that follow.

What is claimed is:

1. A method for forming gate dielectric layers on a substrate, comprising:
forming a silicon oxide layer on a silicon substrate;
depositing a silicon nitride layer on the silicon oxide layer by a thermal process to form a gate dielectric layer; and
thermally annealing the substrate.

2. The method of claim 1, wherein the silicon nitride layer and the silicon oxide layer have a total thickness less than about 30 Å.

3. The method of claim 1, further comprising:
precleaning the substrate prior to forming the silicon oxide layer.

4. The method of claim 3, wherein the step of precleaning the substrate further comprises:
removing native oxides formed on the substrate.

5. The method of claim 1, wherein the step of forming the silicon oxide layer further comprises:
plasma treating the silicon oxide layer deposited on the substrate.

6. The method of claim 1, wherein the step of depositing the silicon nitride layer further comprises:
plasma treating the silicon nitride layer deposited on the substrate.

7. The method of claim 1, wherein the step of forming the silicon oxide layer further comprises:
forming the silicon oxide to a thickness less than about 15 Å.

8. The method of claim 1, wherein depositing the silicon nitride layer further comprises:
depositing the silicon nitride to a thickness less than about 15 Å.

9. The method of claim 1, wherein the step of depositing the silicon nitride layer further comprises:
flowing a gas mixture including a nitrogen containing gas and a silicon containing gas into a process chamber.

10. The method of claim 9, wherein the nitrogen containing gas is selected from a group consisting of NH₃, N₂, and N₂O.

11. The method of claim 9, wherein the silicon containing gas is selected from a group consisting of SiH₄, Si₂H₆, dichlorosilane (DCS), tetrachlorosilane (TCS), and hexachlorodisilane (HCD).

12. The method of claim 1, wherein the step of annealing further comprising:
exposing the substrate in a thermal anneal process chamber.

13. The method of claim 12, wherein the step of exposing the substrate further comprises:
maintaining a substrate temperature between about 600 degrees Celsius and about 1200 degrees Celsius; and
supplying an annealing gas into the thermal anneal process chamber.

14. The method of claim 13, wherein the annealing gas is at least one of O₂. O₃, H₂O, NO, N₂O, NO₂, N₂O₅, N₂, NH₃ or N₂H₄.

15. A method for forming a gate dielectric layer on a substrate, comprising:
forming a silicon oxide layer on a silicon substrate with a thickness less than 15 Å;
depositing a silicon nitride layer on the silicon oxide layer with a thickness less than 15 Å by a thermal process, wherein the silicon oxide layer and the silicon nitride layer are utilized as a gate dielectric layer in a gate structure; and
thermally annealing the substrate.

16. The method of claim 15, wherein the gate dielectric layer has a total thickness less than 30 Å.

17. The method of claim 15, wherein the step of forming the silicon oxide further comprising:
plasma treating the silicon oxide layer on the substrate.

18. The method of claim 15, wherein the step of depositing the silicon nitride layer further comprising:
plasma treating the silicon nitride layer on the substrate.

19. The method of claim 15, further comprises:
precleaning the substrate prior to depositing the silicon oxide layer.

20. A method for forming a gate dielectric layer on a substrate, comprising:
forming a silicon oxide layer on the silicon substrate with a thickness less than 15 Å;
plasma treating the silicon oxide layer;
depositing a silicon nitride layer on the silicon oxide layer with a thickness less than 15 Å by a thermal process to form a gate dielectric layer;
plasma treating the silicon nitride layer; and
thermally annealing the substrate.

21. The method of claim 20, wherein the gate dielectric layer has a total thickness less than about 25 Å.
